(19) United States
(12) Patent Application Publication
(10) Pub. No.: US 2014/0287565 A1
(43) Pub. Date: Sep. 25, 2014

(54) METHOD FOR MANUFACTURING SEMICONDUCTOR STRUCTURE

(71) Applicants: Haizhou Yin, Poughkeepsie, NY (US); Weize Yu, Yujiang (CN)

(72) Inventors: Haizhou Yin, Poughkeepsie, NY (US); Weize Yu, Yujiang (CN)

(21) Appl. No.: 14/354,894

(22) PCT Filed: Dec. 2, 2011
(86) PCT No.: PCT/CN2011/083330

§ 371 Date: Apr. 28, 2014

(30) Foreign Application Priority Data
Nov. 8, 2011 (CN) 201110351250.5

(51) Int. Cl. H01L 29/66

(52) U.S. Cl. CPC H01L 29/66545
USPC 438/308

(57) ABSTRACT

The present invention provides a method for manufacturing a semiconductor structure, which comprises: a) providing a substrate (100); b) forming a dummy gate stack on the substrate (100), wherein the dummy gate stack consists of a gate dielectric layer (203) and a dummy gate (201) located on the gate dielectric layer (203), and the material of the dummy gate (201) is amorphous Si; c) performing ion implantation to regions exposed on both sides of the dummy gate (201) on the substrate (100), so as to form source/drain regions (110); d) forming an interlayer dielectric layer (400) that covers the source/drain regions (110) and the dummy gate stack; e) removing part of the interlayer dielectric layer (400) to expose the dummy gate (201) and removing the dummy gate (201); and f) annealing to activate dopants in source/drain regions. Procedures of the traditional gate-replacement process have been modified by the method for manufacturing a semiconductor structure provided by the present invention, thus etching period can be easily controlled, etching difficulty is alleviated, and stability of etching process is guaranteed as well.

The present application claims priority benefit of Chinese patent application No. 201110351250.6, filed on 8 Nov. 2011, entitled “METHOD FOR MANUFACTURING SEMICONDUCTOR STRUCTURE”, which is herein incorporated by reference in its entirety.

### FIELD OF THE INVENTION

The present invention relates to semiconductor manufacturing field, particularly, to a method for manufacturing a semiconductor structure.

### BACKGROUND OF THE INVENTION

The gate-replacement process in prior art comprises following steps: forming a dummy gate and sidewall spacers surrounding the dummy gate on a substrate, forming source/drain regions by ion implantation and annealing to the substrate, and removing the dummy gate. Wherein, amorphous Si is usually selected as a material for the dummy gate, and annealing process may be implemented at a temperature around 1050° C. When annealing process is performed to the substrate, at least part of the amorphous Si that forms the dummy gate is transformed to poly-Si, whereas crystal orientations of poly-Si grains are uncertain, which nonetheless causes difficulty in controlling etching and removing the dummy gate at subsequent steps, for example, difficulty in controlling etching a poly-Si dummy gate with TMAH.

Specifically speaking, in the case of etching crystal plane {111}, {110} or {100} of poly-Si grains, etching speeds thereof differ significantly. Consequently, etching becomes nonuniform at the time of removing a poly-Si dummy gate. Usually, etching time is estimated in relating to crystal plane { 111 }, which is etched at slowest speed. Given that gate length is short, width of grains might be as great as gate length, and the dummy gate may be occupied by a grain completely, etching may become very difficult if crystal plane {111} of the poly-Si dummy gate faces upwards.

### SUMMARY OF THE INVENTION

The present invention aims to provide a semiconductor structure and a method for manufacturing the same, in order to alleviate etching difficulty or nonuniformity in relating to dummy gates, which still remains in gate-replacement process in the prior art.

The present invention provides a method for manufacturing a semiconductor structure, which comprises following steps:
a) providing a substrate;
b) forming a dummy gate stack on the substrate; wherein the dummy gate stack consists of a gate dielectric layer and a dummy gate located on the gate dielectric layer, and the material of the dummy gate is amorphous Si;
c) performing ion implantation to regions exposed on both sides of the dummy gate on the substrate, so as to form source/drain regions;
d) forming an interlayer dielectric layer that covers the source/drain regions and the dummy gate stack;
e) removing part of the interlayer dielectric layer to expose the dummy gate and removing the dummy gate; and
f) annealing to activate dopants in source/drain regions.

Procedures of the traditional gate-replacement process have been modified by the method for manufacturing a semiconductor structure provided by the present invention, which proposes to remove dummy gate first and then to perform annealing process to source/drain regions; because the material of the dummy gate still remains in state of amorphous Si, thus etching period can be easily controlled, etching difficulty is alleviated, and stability of etching process is guaranteed as well.

### BRIEF DESCRIPTION OF THE DRAWINGS

Other characteristics and advantages of the present invention are made more evident and easily understood according to perusal of following detailed description of exemplary embodiment(s) in conjunction with accompanying drawings, wherein:

FIG. 1 illustrates a flowchart of a method for manufacturing a semiconductor structure according to an embodiment of the present invention; and

FIG. 2 to FIG. 8 illustrate cross-sectional structural diagrams of the semiconductor structure at respective stages of a method for manufacturing a semiconductor structure according to the flowchart of the embodiment of the present invention as shown in FIG. 1;

Same or similar reference signs in accompanying drawings denote same or similar elements.

### DETAILED DESCRIPTION OF THE INVENTION

Objectives, technical solutions and advantages of the present invention are made more evident according to the following detailed description of exemplary embodiments in conjunction with accompanying drawings.

Embodiments of the present invention are described in detail here below, wherein examples of embodiments are illustrated in drawings, in which same or similar reference signs throughout denote same or similar elements or elements have same or similar functions. It should be appreciated that the embodiments described below in conjunction with drawings are illustrative and are provided for explaining the prevent invention only, thus shall not be interpreted as limitations to the present invention.

Various embodiments or examples are provided here below to achieve different structures of the present invention. To simplify disclosure of the present invention, description of components and arrangements of specific examples is given below. Of course, they are illustrative only and not limiting the present invention. Moreover, in the present invention, reference numbers and/or letters may be repeated in different embodiments. Such repetition is for purposes of simplification and clarity, yet does not denote any relationship between respective embodiments and/or arrangements being discussed. Furthermore, the present invention provides various examples for specific process and materials. However, it is obvious for a person of ordinary skill in the art that other processes and/or materials may be utilized alternatively. In addition, the following structure in which a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other.

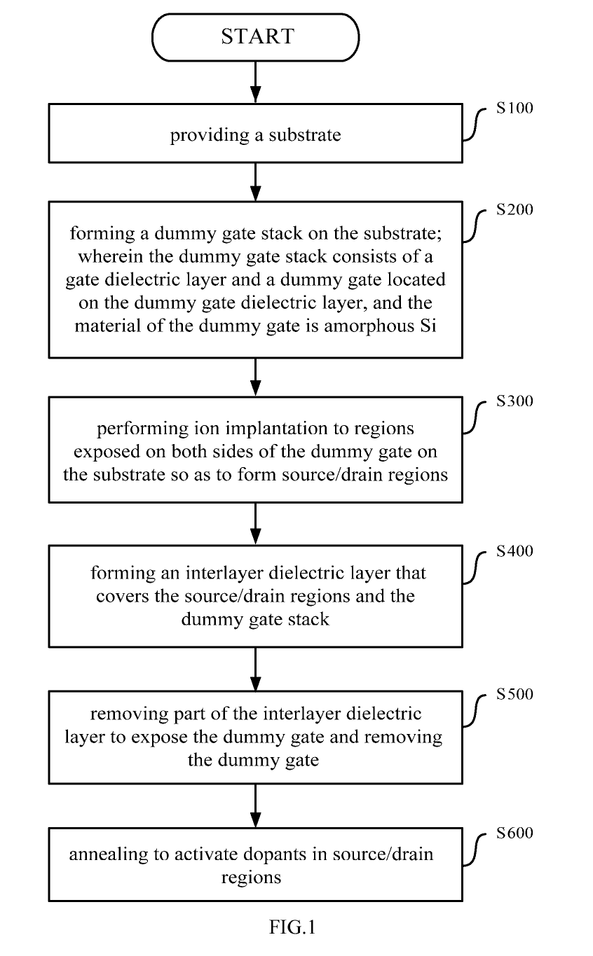

With reference to FIG. 1, which illustrates a flowchart of a method for manufacturing a semiconductor structure according to an embodiment of the present invention, the method comprises:

at step S100, providing a substrate;

at step S200, forming a dummy gate stack on the substrate, wherein the dummy gate stack consists of a gate dielectric layer and a dummy gate located on the gate dielectric layer, and the material of the dummy gate is amorphous Si;

at step S300, performing ion implantation to regions exposed on both sides of the dummy gate on the substrate so as to form source/drain regions;

at step S400, forming an interlayer dielectric layer that covers the source/drain regions and the dummy gate stack;

at step S500, removing part of the interlayer dielectric layer to expose the dummy gate, and removing the dummy gate;

at step S600, annealing to activate dopants in source/drain regions.

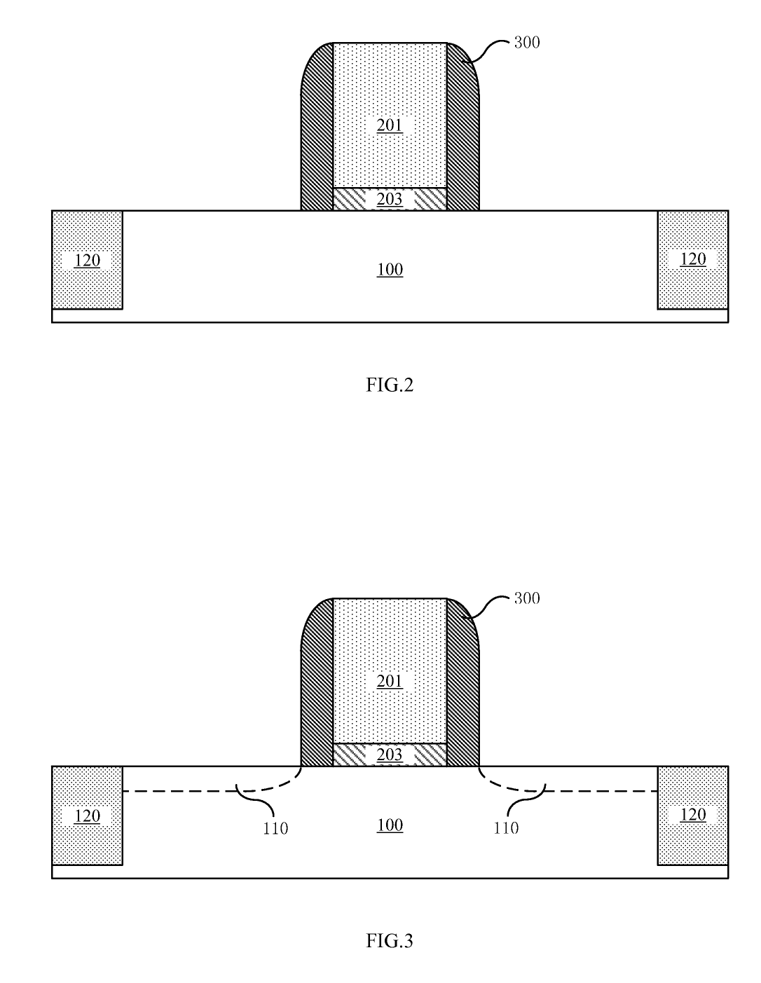

Steps S100 to S600 are described in conjunction with FIG. 2 through FIG. 8; wherein FIG. 2 to FIG. 8 illustrate cross-sectional structural diagrams of the semiconductor structure at respective stages of a method for manufacturing a semiconductor structure according to the flowchart of the embodiment of the present invention as shown in FIG. 1. It should be noted that drawings for embodiments of the present invention are illustrative only, thus are not drawn in proportion.

First, step S100 is implemented to provide a substrate 100. The substrate 100 includes Si substrate (e.g. Si wafer). According to design specifications known in the prior art (e.g. a P-type substrate or an N-type substrate), the substrate 100 may be of various doping configurations. The substrate 100 in other embodiments may further include other semiconductor, for example germanium. Alternatively, the substrate 100 may include a compound semiconductor, for example SiC, GaAs, InAs or InP. The substrate 100 is a Si substrate in the present embodiment. Typically, the substrate 100 may have, but is not limited to, a thickness of around several hundred micrometers, which for example may be in the range of 400 μm-800 μm. With reference to FIG. 2, an isolation region 120 has already been formed in the substrate 100 in an embodiment of the present invention, for example, an STI region. The material of the isolation region 120 is an insulating material, which for example may be SiO₂ or Si₃N₄; width of the isolation region 120 is decided in view of design requirements of the semiconductor structure.

With reference to FIG. 2, step S200 is implemented to form a dummy gate stack on the substrate 100; the dummy gate stack consists of a gate dielectric layer 203 and a dummy gate 201 located on the gate dielectric layer 203; the material of the dummy gate 201 is amorphous Si. Specifically, a gate dielectric layer 203 is deposited on the substrate at first, and then an amorphous Si layer is deposited to cover the gate dielectric layer 203. The gate dielectric layer 203 and the amorphous Si layer may be formed by means of Chemical Vapor Deposition (CVD), Plasma Enhanced CVD, High-density Plasma CVD, Atomic Layer Deposition (ALD), Plasma Enhanced Atomic Layer Deposition (PEALD), Pulsed Laser Deposition (PLD) or other method as appropriate. The gate dielectric layer 203 may comprise a thermal oxide layer including SiO₂ or SiOₓN_{y}, or a high-k dielectric material selected from a group consisting of, for example, HfO₂, HfSiO, HfSiON, HfTaO, HfTiO, HfZrO, Al₂O₃, La₂O₃, ZrO₂ and LaAlO or combinations thereof, whose thickness is, for example, in the range of 1 nm˜4 nm.

Moreover, a photoresist layer is formed on the amorphous Si layer, the photoresist layer may comprise a material selected from a group consisting of vinyl monomer, quinone azide compound and Polyethylene monolaurate or the like. The photoresist layer is patterned through lithography to form a gate line pattern, then the amorphous Si layer not covered by the photoresist layer and the gate dielectric layer 203 beneath the amorphous Si layer are etched so as to form the dummy gate stack consisting of the dummy gate 201 and the dummy gate dielectric layer 203.

Optionally, light doping may be performed to the substrate 100 on both sides of the dummy gate stack so as to form source/drain extension regions. Halo implantation may be further implemented so as to form Halo regions. Wherein, the type of dopants for light doping is consistent with that of the device, while the type of dopants for Halo implantation is contrary to that of the device. Namely, in case of an NMOS device, the source/drain extension regions are N-type doped, while the dopants for Halo implantation is P-type; in case of a PMOS device, the source/drain extension regions are P-type doped, while the dopants for Halo implantation is N-type.

Next, optionally, sidewall spacers 300 are formed adjoining opposite sidewalls of the dummy gate stack for purpose of isolating the dummy gate stack. The sidewall spacers 300 may be formed with Si₃N₄, SiO₂, SiOₓN_{y}, SiC and/or other material as appropriate. The sidewall spacers 300 may have a multi-layer structure. The sidewall spacers 300 may be formed by means of depositing-etching process, whose thickness is, for example, in the range of about 10 nm-100 nm. The sidewall spacers 300 surround the dummy gate stack.

Next, with reference to FIG. 3, step S300 is carried out to implement ion implantation to regions exposed on both sides of the dummy gate 201 on the substrate 100, so as to form source/drain regions 110 in the substrate 100; wherein the source/drain regions 110 may be formed through a method including lithography, ion implantation, diffusion and/or other method as appropriate. Typically, the source/drain regions 110 are formed by means of ion implantation in the present embodiment. Ion implantation means to accelerate dopants (voltage≧105V for Si), such that the dopants, which have gained significant kinetic energy, can come into the substrate 100 directly and yet give rise to some crystal lattice defects in the substrate 100; therefore, low temperature annealing or laser annealing has to be performed after ion implantation in order to eliminate aforesaid defects.

The type of dopants for source/drain implantation is same as that of the device. Namely, in case of an NMOS device, the dopants for source/drain implantation are N-type; in case of a PMOS device, the type of dopants for source/drain implantation is P-type. In the present embodiment, the source/drain regions 110 are located within the substrate 100. However, in other embodiments, source/drain regions 110 may be raised source/drain structures formed by selective epitaxial growing method, wherein the heads of epitaxial portions thereof are higher than the bottom of the dummy gate stack (herein, the bottom of the dummy gate stack indicates the boundary plane of the dummy gate stack and the substrate 100). For example, the raised portions of source/drain regions 110 may be P-type doped SiGe for PMOS, while the raised portions of the source/drain regions 110 may be N-type doped Si for NMOS.

In other embodiments, ion implantation at step S200 may be carried out to form source/drain regions 110 in the substrate 100, prior to formation of sidewall spacers 300; namely, the sidewall spacers 300 may be formed either before or after formation of source/drain regions 110.

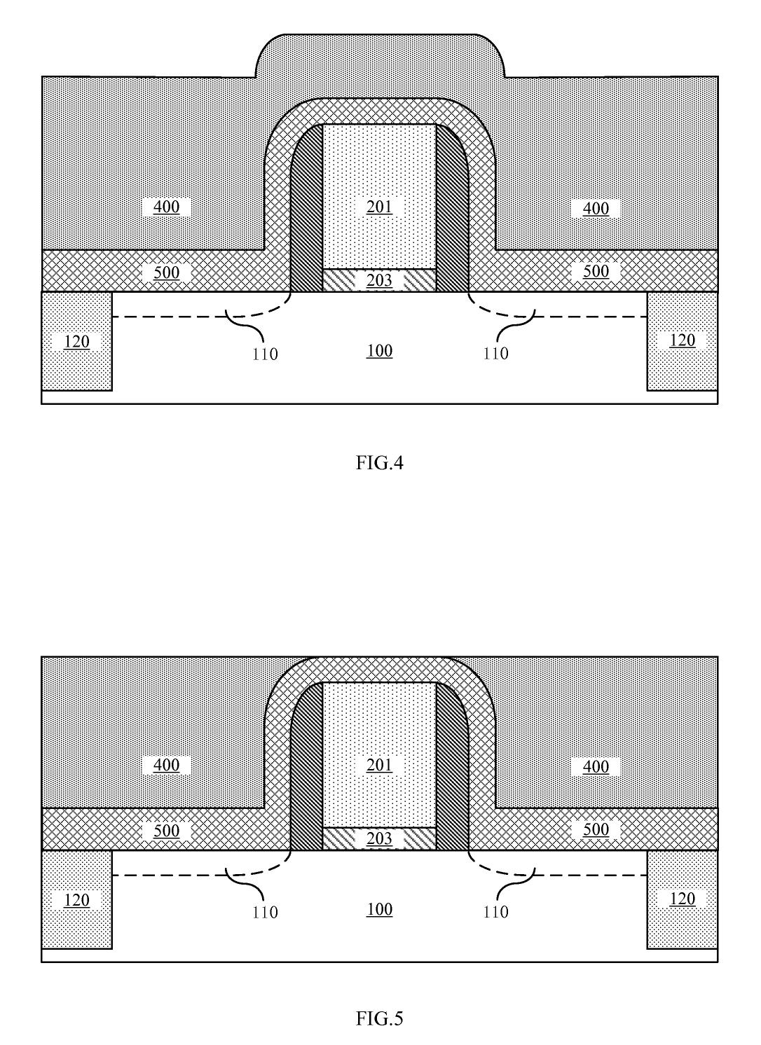

Preferably, with further reference to FIG. 4, step S400 is carried out to form an interlayer dielectric layer 400 that covers the source/drain regions 110 and the dummy gate stack. Particularly, an etching stop layer 500 may be formed firstly on the semiconductor structure to cover the semiconductor structure, as shown in FIG. 4. The etching stop layer 500 may be formed with a material like Si₃N₄, SiOₓN_{y}, SiC and/or other material as appropriate. The etching stop layer 500 may be formed by means of, for example, CVD, Physical Vapor deposition (PVD), ALD and/or other method as appropriate. The thickness of the etching stop layer 500 is in the range of 5 nm˜20 nm in an embodiment. As stated above, since the etching stop layer 500 has been formed in advance, thus the interlayer dielectric layer 400 is formed on the etching stop layer 500. The interlayer dielectric layer 400 may be formed on the etching stop layer 500 by means of CVD, Plasma Enhanced CVD, High-density Plasma CVD, spin coating or other method as appropriate. The interlayer dielectric layer 400 may comprise a material selected from a group consisting of SiO₂, carbon doped SiO₂, BPSG, PSG, UGS, SiOₓN_{y} and a low-k material, or combinations thereof. The thickness of the interlayer dielectric layer 400 may be in the range of 40 nm-150 nm, for example, 80 nm, 100 nm or 120 nm.

In other embodiments of the present invention, it is also applicable not to form the etching stop layer 500 but to directly form the interlayer dielectric layer 400 that covers the source/drain regions 110 and the dummy gate stack.

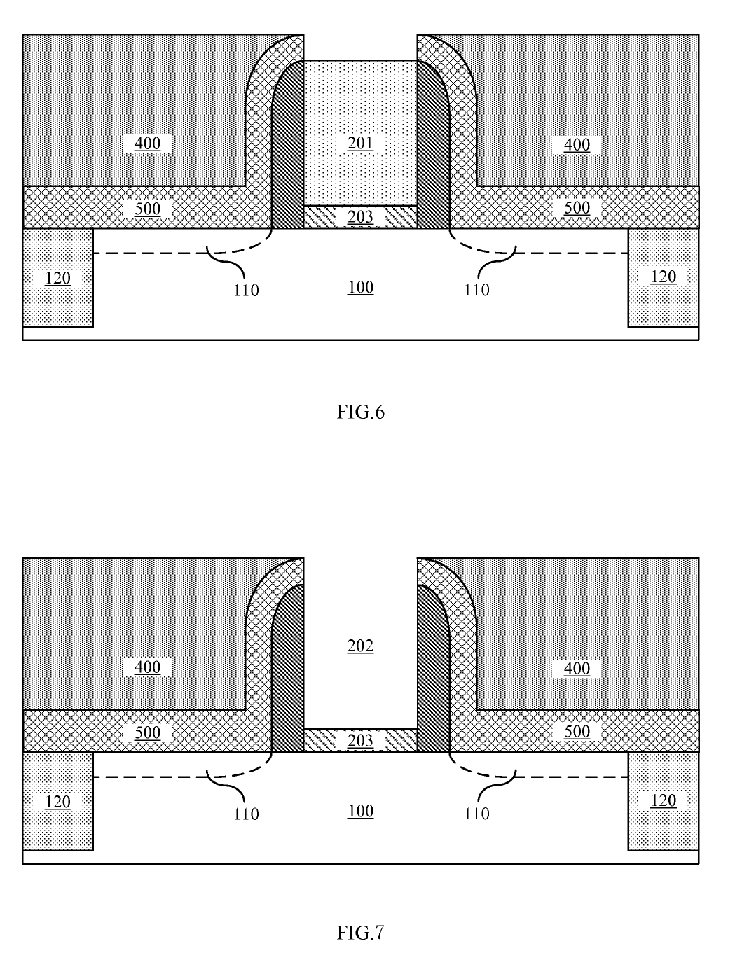

With reference to FIG. 5, FIG. 6 and FIG. 7, step 5500 is carried out to remove part of the interlayer dielectric layer 400 to expose the dummy gate 201 and to remove said dummy gate 201. As shown in FIG. 5, planarizing process is performed such that the etching stop layer 500 on the gate stack is exposed and becomes at the same level as the interlayer dielectric layer 400 (herein, the term “at the same level” means that the difference between heights of two objects is in the permitted range of technical error). However, it should be noted that the material of the etching stop layer 500 has greater hardness than that of the material of the interlayer dielectric layer 400, in order to guarantee that chemical mechanical polish (CMP) stops on the etching stop layer 500.

Then, with reference to FIG. 6, the exposed etching stop layer 500 is etched selectively, so as to expose the dummy gate 201. The etching stop layer 500 may be removed through wet etching and/or dry etching. Wet etching process includes chemicals such as hydroxide solution (e.g. ammonium hydroxide), deionized water or other etching solution as appropriate; dry etching process includes, for example, plasma etching. In other embodiments of the present invention, the etching stop layer 500 may be planarized by means of CMP technology until the dummy gate 201 is exposed, since this also can achieve the purpose of removing the etching stop layer 500 above the dummy gate 201.

In embodiments without etching stop layer 500, part of the interlayer dielectric layer 400 may be removed through CMP process until the dummy gate 201 is exposed.

Then, the dummy gate 201 is removed, which is stopped on the gate dielectric layer 203, as shown in FIG. 7. The dummy gate 201 may be removed through wet etching and/or dry etching. Plasma etching is used in an embodiment. Specifically, the dummy gate 201 made of amorphous Si material is etched and removed using TMAH in the present embodiment, wherein TMAH denotes Tetramethy ammonium hydroxide, and solutions of 10% and 25% TMAH in water are usually used for etching. Processes of etching and removing the dummy gate 201 with TMAH are widely known in the prior art, thus it is not described in detail here in order not to obscure. Since the amorphous Si dummy gate has never gone through a high-temperature treatment, thus it still remains in amorphous state; accordingly, the whole wafer shows good uniformity during etching process with TMAH, thus the processing period can be easily controlled.

With reference to FIG. 7, a trench 202 surrounded by sidewall spacers 300 is formed after completely removal of the dummy gate 201; then, step S600 is carried out to implement annealing to activate dopants in source/drain regions. Wherein, the temperature for annealing is in the range of 900° C. to 1200° C., which is preferably around 1050° C. In an embodiment, the semiconductor structure may be annealed through instant annealing process, for example laser annealing at a temperature as high as about 800° C.-1100° C.

Additionally, further annealing may be implemented for restoring the gate dielectric layer 203. Or, optionally, the gate dielectric layer 203 deposited previously may be removed so as to deposit a new gate dielectric layer then. Accordingly, the newly formed gate dielectric layer may be formed at the bottom of the trench 202 and covers the upper surface of the substrate 100 exposed from the trench 202. The newly formed gate dielectric layer may comprise a thermal oxide layer including SiO₂ or SiOₓN_{y}, or a high-k dielectric consisting of, for example, HfO₂, HfSiO, HfSiON, HfTaO, HfTiO, HfZrO, Al₂O₃, La₂O₃, ZrO₂ and LaAlO or combinations thereof. The thickness thereof is, for example, in the range of 1 nm˜4 nm.

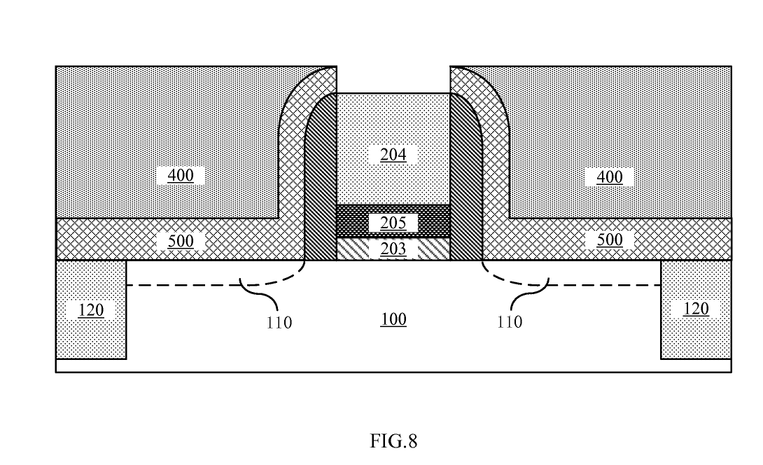

Typically, the semiconductor structure as shown in FIG. 7 is further processed in the subsequent procedure after completion of step S600. With reference to FIG. 8, for example, a replacement gate is formed in the trench 202. The replacement gate is a metal gate in an embodiment. The metal gate may comprise a metal conductor layer 204 only, and the metal conductor layer 204 may be formed directly on the gate dielectric layer 203. In other embodiments, the metal gate may further comprise a work function metal layer 205 and a metal conductor layer 204.

As shown in FIG. 8, preferably, the work function metal layer 205 is deposited firstly on the gate dielectric layer 203, then the metal conductor layer 204 is formed on the work function metal layer 205. The work function metal layer 205 may be formed with a material like TiN, TaN, whose thickness is in the range of 3 nm˜15 nm. The metal conductor layer 205 may have a single layer or multi-layer structure, and may comprise a material selected from a group consisting of TaN, TaC, TiN, TaAlN, TiAlN, MoAlN, TaTbN, TaErN, TaYbN, TaSiN, HfSiN, MoSiN, RuTaₓ and NiTaₓ or combinations thereof. The thickness thereof may be in the range of 10 nm-80 nm, for example, 30 nm or 50 nm.

In an embodiment, preferably, the work function metal layer 205 may be formed on the gate dielectric layer 203 in the former steps, thus the work function metal layer 205 is exposed after the dummy gate 201 has been removed, and then the metal conductor layer 204 is formed on the work function metal layer 205 within the opening formed previously. Since the work function metal 205 has been formed on the gate dielectric layer 203, therefore, the metal conductor layer 204 is formed on the work function metal layer 205.

Procedures of the traditional gate-replacement process have been modified by the method for manufacturing a semiconductor structure provided by the present invention, which proposes to remove dummy gate 201 firstly and to perform annealing then; because the material of the dummy gate 201 still remains in state of amorphous Si before implementation of annealing process, thus etching period becomes easy to control, etching difficulty is alleviated, and stability of etching process is guaranteed as well.

Although exemplary embodiments and their advantages have been described in detail, it should be understood that various alternations, substitutions and modifications may be made to the embodiments without departing from the spirit of the present invention and the scope as defined by the appended claims. For other examples, it may be easily recognized by a person of ordinary skill in the art that the order of processing steps may be changed without departing from the scope of the present invention.

In addition, the scope to which the present invention is applied is not limited to the process, mechanism, manufacture, material composition, means, methods and steps described in the specific embodiments in the specification. According to the disclosure of the present invention, a person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

What that is claimed is:

1. A method for manufacturing a semiconductor structure, comprising:
a) providing a substrate (100);
b) forming a dummy gate stack on the substrate (100); wherein the dummy gate stack consists of a gate dielectric layer (203) and a dummy gate (201) located on the dummy gate dielectric layer (203), and the material of the dummy gate (201) is amorphous Si;
c) performing ion implantation to regions exposed on both sides of the dummy gate (201) on the substrate (100) so as to form source/drain regions (110);
d) forming an interlayer dielectric layer (400) that covers the source/drain regions (110) and the dummy gate stack;
e) removing part of the interlayer dielectric layer (400) to expose the dummy gate (201) and removing the dummy gate (201); and
f) annealing to activate dopants in source/drain regions.

2. The method of claim 1, wherein the step a) further comprising: forming an isolation region (120) in the substrate (100).

3. The method of claim 1, wherein the step b) further comprising: forming sidewall spacers (300) surrounding the dummy gate stack, after formation of the dummy gate stack.

4. The method of claim 1, wherein:
the interlayer dielectric layer (400) comprises a material selected from a group consisting of SiO₂, carbon doped SiO₂, BPSG, PSG, USG, Si₃N₄ and low-k material or combinations thereof.

5. The method of claim 1, wherein step e) comprising:
removing the dummy gate (201) with TMAH solution.

6. The method of claim 1, wherein:
the temperature for annealing at step f) is in the range of 900° C. to 1200° C.
